(19) United States
(12) Patent Application Publication
(10) Pub. No.: US 2022/0298669 A1
(43) Pub. Date: Sep. 22, 2022

(54) METHODS, SYSTEMS, AND APPARATUSES FOR A REACTOR

(71) Applicant: Quantum Photonics Corporation, Tyler, TX (US)

(72) Inventors: Matthew Ryan HANKLA, Tyler, TX (US); Mary MCINERNY, Tyler, TX (US)

(73) Assignee: Quantum Photonics Corporation, Tyler, TX (US)

(21) Appl. No.: 17/699,566

(22) Filed: Mar. 21, 2022

Related U.S. Application Data
(60) Provisional application No. 63/164,093, filed on Mar. 22, 2021.

(51) Int. Cl. C30B 15/10; C30B 23/02

(52) U.S. Cl. CPC C30B 15/10; C30B 23/02

(57) ABSTRACT

Methods, systems, and apparatuses for generating, producing, and utilizing energy.

Aspects of the invention are disclosed in the following description and related drawings directed to specific embodiments of the invention. Those skilled in the art will recognize that alternate embodiments may be devised without departing from the spirit or the scope of the claims. Additionally, well-known elements of exemplary embodiments of the invention will not be described in detail or will be omitted so as not to obscure the relevant details of the invention. Further, to facilitate an understanding of the description discussion of several terms used herein follows.

As used herein, the word “exemplary” means “serving as an example, instance or illustration.” The embodiments described herein are not limiting, but rather are exemplary only. It should be understood that the described embodiment are not necessarily to be construed as preferred or advantageous over other embodiments. Moreover, the terms “embodiments of the invention”, “embodiments” or “invention” do not require that all embodiments of the invention include the discussed feature, advantage or mode of operation.

In an exemplary embodiment, a Reactor may be provided.

Starting with raw materials, the chemical compound aluminum oxide, Al₂O₃, is put into a crucible and synthetically grown and doped with titanium creating Ti³⁺:Al₂O₃. This new compound is known as Titanium-Sapphire. Ti-Sapphire is a unique crystal that when stimulated by a specific wavelength of light, has been known as a tunable gain medium. Currently, Ti-Sapphire is frequently used in many different laser systems due to its unique index of refraction and varying orientations. It was not until very recently that it was discovered that there was a way to both harness and sustain the gain of the Ti-Sapphire. With this revolutionary discovery, the creation of the world's first energy generation device was conceptualized and patented.

Crystal Growth Process

To grow a crystal with a tunable gain medium, a specific type of container, such as a crucible or some other type of container that can withstand high temperatures for long periods of time, may be needed to grow the chemical compound from the raw materials into a larger crystalline structure, such as a boule. A crucible of a specific size that uses an exemplary growth method, such as the heat exchange method (HEM), the Czocharlski method, or any other type of exemplary crystal growth process may be used to grow a crystal with a tunable gain medium.

Raw materials of a specific measurement are put into the crucible and are heated to a certain degree. These raw materials include aluminum oxide Al₂O₃, or any other type of crystalline compound. During this heat exchange, the Al₂O₃ is melted down into its liquid form. A dopant such as titanium (IV) oxide (TiO₂), or any other type of metallic compound, is then introduced to the aluminum oxide and will ionically bind to form a new compound known as Ti³⁺:Al₂O₃.

Epitaxial growth may also be used to combine the dopant, such as titanium (IV) oxide (TiO₂), or any other type of metallic compound, with the melt. This process may include the inclusion of controlled gas pressure, including but not limited to controlled oxygen pressure gas. This process is performed at a specific temperature, such as 700 degrees Celsius, or any other temperature that allows for the TiO₂ to bind with the melt.

The crucible may use a specific gas, such as Argon, that creates a partial pressure causing the Ti³⁺ ions to combine with the aluminum oxide creating a specific crystalline lattice structure that is intrinsic to the material. The gas may not be reactive due to its stable electron structure and will not interact with the exemplary material. A seed of a specific chemical compound is then inserted into the melt and grows the material into a boule of Ti³÷:Al₂O₃. The boule is grown into a specific size and removed from the crucible. The size of the boule may be 200 mm in diameter but may be larger or smaller as well.

Characterization of Ti-Sapphire

Once it is removed, it then can be characterized through an exemplary process, such as x-ray diffraction, spectroscopy, or any other type of exemplary characterization method. The boule may be characterized by its orientation, dopant level, and level of homogeneity.

The crystal may be oriented on a variety of different axis such as the A-axis, M-axis, C-axis, or any other axis on the crystal. The crystal may also be oriented on a random axis as well.

The dopant level may include a range from 1.5 to 5 but may also be higher or lower as well. The level of the titanium will dictate how highly doped the Ti-Sapphire is and may affect the index of refraction of the material.

The level of homogeneity may be dependent on the crystalline lattice structure of material. If the Ti³⁺:Al₂O₃ has a consistent structure and bond throughout the axis of which it has been oriented on, it may be considered more homogeneous. When the crystal has a high level of homogeneity, light may be able travel through the material with limited interruption.

Coring of the Boule

After the boule has been characterized, it may undergo the next phase in the manufacturing process. Before the Ti-Sapphire is cut, a core may be drilled out of the boule. The core can come from the middle or any other part of the boule that is most homogenous.

This process may then result with a long rod of a specific diameter and length depending upon the size needed.

Cutting the Rod

Once the rod has been obtained, the material can then be cut into pieces of a specific size and diameter including, but not limited to a square, rectangle, or circular shape. The core may be cut on a specific axis such as the A, M, or any other axis of the crystal.

To initiate cutting process, the Ti-Sapphire may be mounted to a part of the wire saw that enables the Ti-Sapphire to be lowered evenly onto the cutting wire. The crystal may be mounted to the wire saw using a specific chemical compound that may hold the crystal in place as it is cut.

The cutting wire may be made of a variety of materials impregnated with diamond, or any other type of molecule, or compound, that may be durable enough to cut through Ti-Sapphire.

The machine may emit a particular aqueous chemical substance that may wash away excess debris and may also keep the crystal cool as the crystal is cut.

As the wire saw rocks, the wire may cut through a particular axis of the Ti-Sapphire. The wire may cut the sapphire straight down the crystal or it may cut the crystal at a specific curvature depending upon which cut creates a gain that is most efficiently harnessed.

Cleaning of the Ti-Sapphire

This process may continue until the wire has cut through the crystal cleanly. The Ti-Sapphire may be removed from the wire-saw and then rinsed in a bath composed of specific chemicals that may have the ability to rinse the crystal and remove any extra particles.

After the Ti-Sapphire has been rinsed, it may then be placed in a tub of boiling water. This allows for the crystal to be removed from the adhesive. The adhesive may be composed of specific chemical compounds that may allow the crystal to remain attached to the wire saw during the cutting process.

At this point, the cut Ti-Sapphire is known as a ‘reactor’; the part of the ‘power core’ that allows for the spontaneous creation and emission of new photons of the device.

Polishing the Blanks

The reaper is then polished and fabricated. During this process, the reactor's edges may be cut straight, beveled, or in any other way that allows for the reaper to harness more photonic energy. The reactor is then cut at specific angles at each of the sides. These angles can be cut at 90°, 60.4° also known as a Brewster angle, or at any other angle that prevents the escape of light from the material.

If when using a Brewster cut, the angle may be on the A plane, the M plane, both, and/or any other plane of the reaper. This specific angling may allow for photons to bounce off the angle and exit the material at a different plane, such as the C, or any other plane of the reaper.

Once the reactor has been angled, it may undergo the next stage of polishing. The polishing can be composed of several steps that lead to a completely smooth and glossy reaper. These steps may include, but are not limited to, chemical mechanical polishing, or any other type of crystal polishing.

During this process, the reactor is held with pads of a specific material that does not scratch the surface of the reactor and may remove any roughness of the material to produces a glossy finish. The pads can be made of polyurethane, politex, or any other type of material that effectively polishes the reactor. The pads rotate at a specific speed and rate, including but not limited to 100 rotations per minute, or any other specific number of rotations per minute that enable the material to become effectively polished.

This process also may include a type of liquid that continuously washes away any fragments and keeps the material cool. The slurry may be silica based, aluminum based, or any other type of chemical compound that keeps the material clean as the pads polish the material.

Once the reactor has become effectively polished, it may be ready for the next stage in the manufacturing process.

Coating the Ti-Sapphire

The reactor may be coated with a variety of exemplary coatings that may regulate the amount of light that is both harnessed and emitted by the reactor. Coatings may be on just one side, or on every side of the reactor, depending upon which design works most efficiently in modulating photonic energy retainment and emission.

Antireflective (AR) coatings may be placed on the sides, ends, or faces of the reactor depending upon the orientation of the material and which side is meant to easily transmit photonic energy. This AR coating may be made of specific chemical or molecular compound that effectively allows for wavelengths within the absorption spectrum of the reactor to enter the substrate with minimal reflection losses. This may be completed by the AR coating's ability to effectively produce two reflections that interfere destructively with one another allowing for seamless transmission of photonic energy within the bandgap that the AR is tuned specifically. There may be one or more layers of AR coatings on any side of the reactor.

Antireflective coatings may be deposited onto the substrate using a variety of different coating deposition methods. Some include, but are not limited to electron beam sputtering, electron beam physical vapor deposition, ion assisted deposition, ion beam sputtering, or any other type of coating process that allows for the effective and efficient deposition of antireflective coatings upon the surface of a substrate. When using electron beam sputtering, a possible adhering process is as follows.

To initiate this process, the coating material may be heated within a high vacuum chamber until it becomes vaporized. It may be heated through electron beam bombardment when using dielectrics, or it may be heated resistively when using metals. As the coating material vaporizes, vapor may then stream away and recondense onto the surface of the substrate intended for coating.

Another process that may be utilized when using electron beam sputtering includes electron-beam physical vapor deposition. This may allow for coating at a high deposition rate without needing to heat the substrate at such high temperatures. When initiating this coating process, an electron beam may be generated and accelerated to a high kinetic energy. This high energy beam may then be directed at the evaporation material causing the electrons within the material to decrease unto a lower energy level. Interactions with the evaporation material causes kinetic energy to become converted into alternative forms of energy. Thermal energy may be one of the alternative forms of energy and may conduct heat into the evaporation material causing it to melt. The melt may then vaporize and rise to coat the surface of the substrate.

Highly reflective (HR) coatings may be placed on the sides, ends, or faces of the reactor depending upon the orientation of the material and which side is meant to reflect the photonic energy pumped into the material. This HR coating may be made of a specific chemical or molecular compound that effectively reflect the specific wavelength of photonic energy pumped into the reactor. These compounds may include but are not limited to an aluminum or chromium compound. This may be completed by the HR coating's multilayer system. One layer may be composed of a chemical or molecular compound that has a high index of refraction, such as zinc sulfide or any other type of molecular or chemical compound that has a high index of refraction and is specific to the wavelength of light emitted by the pump source of the reactor. The next layer may be composed of a chemical or molecular compound that has a low index of refraction such as magnesium fluoride or silicon dioxide or any other chemical or molecular compound that has a low index of refraction and is specific to the wavelength of light emitted by the pump source of the reactor. A type of HR coating that may be used is a dielectric mirror. This dielectric coating that can be manipulated with the variation of in thickness of dielectric layers that is specifically designed to reflect a specific wavelength of light. This type of coating is often used in the Ti-Sapphire laser system.

There are multiple ways to adhere this coating to the exemplary embodiment. Of which may include, but are not limited to, electron beam sputtering, electron beam physical vapor deposition, ion assisted deposition, ion beam sputtering, or any other type of coating process that allows for the effective and efficient deposition of highly reflective coatings upon the surface of a substrate.

A possible process when using an ion beam sputtering technique is as follows:

Using a vacuum chamber and a target material (a metal oxide or any other type of material that releases electrons), a high energy ion beam is directed at the target. The ions within the beam may transfer their momentum into the target material causing atoms or molecules to sputter off. These high energy atoms/molecules that may sputter off the target material may deposit onto the substrates. Uniform, high density coatings may be achieved due to the presence of low-pressure oxygen within the coating to re-oxidize any free molecule or atom that may have become dissociated during the sputtering process.

The resulting coating may be an extremely smooth, clean surface finish that may also withstand temperature and humidity fluctuations within its environment.

Dichromatic coatings may also be placed on the sides, ends, or faces of the reactor depending upon the orientation of the material and which side is meant to allow the newly created photonic energy emitted by the reactor to exit the material. This coating may be composed of a variety of layers of differing chemical or molecular compounds that may allow for a specific wavelength of light to exit the material, while simultaneously retaining any other wavelength of light inside the reactor. This allows for reactor to regulate which wavelengths of light are emitted and which wavelengths of light are retained within the material.

There are multiple ways to deposit this coating to the exemplary embodiment. One of which includes evaporating the chemical or molecular compound evenly across the surface. This allows for the coating to bond to the material seamlessly which may enhance its overall effectiveness.

There are a variety of processes that may be used to evaporate this compound onto the surface of the substrate. Some of which include, but are not limited to, electron beam sputtering, electron beam physical vapor deposition, ion assisted deposition, ion beam sputtering, or any other type of optical coating process that allows for the effective distribution of dichroitic coatings.

A possible process when using an ion beam sputtering technique is as follows:

Using a vacuum chamber and a target material (a metal oxide or any other type of material that releases electrons), a high energy ion beam is directed at the target. The ions within the beam may transfer their momentum into the target material causing atoms or molecules to sputter off. These high energy atoms/molecules that may sputter off the target material may deposit onto the substrates. Uniform, high density coatings may be achieved due to the presence of low-pressure oxygen within the coating to re-oxidize any free molecule or atom that may have become dissociated during the sputtering process.

The resulting coating may be an extremely smooth, clean surface finish that may also withstand temperature and humidity fluctuations within its environment.

Once the reactor has been properly coated to meet the specifications that may be needed to modulate the specific wavelengths of light reflected within the material, the specific wavelengths of light that are blocked from exiting the material, and the wavelengths of light that are able to emit from the material, the material may be ready to move on to the next stage of manufacturing.

Implementation of Photon Blasters

A specific kind of light emitting chemical or molecular compound is then adhered to the sides, ends, or face of the reactor. These light emitting chemicals may include light emitting diodes, or any other type of chemical or molecular compounds that emit specific wavelengths of light that are highly transmittable through the reactor. These light emitting materials are further referred to as ‘photon-blasters’.

These photon-blasters may consist of a specific chemical or molecular compound that illuminates a specific wavelength of light that is in the peak absorption range of the reactor. The chemical or molecular compound may include indium gallium nitride (InGaN), aluminum gallium indium phosphide (AlGnInP), aluminum gallium arsenide (AlGaAs), or any other type of chemical or molecular compound that emits a specific wavelength of light that is in the peak absorption range of the reactor.

These photon-blasters may emit a specific wavelength of light that stimulates a quantum photonic phenomenon inside the reactor. This quantum photonic phenomenon includes, but is not limited to, the spontaneous emission of a new photon for every photon pumped into the reactor when the wavelength is in the peak absorption spectrum for the reactor. This wavelength may include, but is not limited to 532 nm, or any other wavelength that is easily absorbed and re-mitted as an alternative wavelength by the reactor.

The photon-blaster may also have a coating over the surface of the material where photons are emitted. This coating may amplify the light stimulated by the photon-blaster. This coating includes Ti³⁺:Al₂O₃, or any other type of chemical or molecular compound that readily amplifies the photonic energy stimulated by the photon blaster.

These photon-blasters may be adhered to the reactor in relation to the coatings and orientation of reactor. These coatings include the antireflective, highly reflective, and/or dichromatic coatings, or any other type of coating on the reactor that alters the index of refraction of the light emitted by the photon blaster. The orientation of the reactor may also dictate where the photon-blaster is placed. The photon-blaster may be adhered to the A-plane, the M-plane, or any other plane that has a specific index of refraction that allows for the photonic energy to easily pass through the reactor and stimulate a specific reaction. Depending upon location of the coatings and the orientation of the material, the photon-blaster will be adhered to the reactor at a specific incidence angle and location that allows for the most photonic energy to saturate the material. When the reactor is saturated, the creation of newly emitted photons is stimulated for every photon pumped into the material.

A specific number of photon-blasters are placed in a specific location on the reactor that allows for the material to completely saturate. This number may include one or more photon blasters deposited on whatever plane or planes that allow for the photonic energy to easily pass through and stimulate the reactor.

The photon-blasters may require a specific amount of power to accurately emit the photonic energy necessary to saturate the reactor. These photon reactors may need an initial jump start from an external photovoltaic that will convert photonic energy from the sun into electrical energy to power the photon-blaster. After this initial jump-start, the creation of new photonic energy resulting from the quantum photonic phenomena within the reactor may be enough to sustainably provide power to the photon-blasters.

The photon-blasters may either stimulate photonic energy in pulses or at a continuous constant wave of photonic energy depending upon which method results in greater amount of photonic energy emitted by the reactor. If constant wave were to create the greatest amount of photonic energy emitted by the reactor, the photon-blasters may breathe on and off as thermal conditions rise within the material. Therefore, if one photon-blaster began to produce a high amount of thermal energy and was at risk for burning out, the next photon-blaster may breathe on at the same rate the other would breathe off. This rate of breathing on and off as thermal conditions become less than ideal, may allow for a constant wave of photonic energy to consistently stimulate the reactor. This process may allow for the potential for continuous photonic energy generation and emission from the reactor.

Depositing the Reapers

The next part of the exemplary embodiment may include the chemical or molecular compound that may be deposited on the specific side of the reactor that emits photonic energy. This side may include the face that consists of the dichromatic coating, or any other type of exemplary coating, that allows for specific wavelengths of light to exit the reactor.

This component with photoreactive capabilities may be known as the ‘reaper’. The reaper consists of a specific chemical or molecular compound that is photoreactive to the specific wavelengths of light emitted by the reactor. The reaper may be a photovoltaic, or any other type of molecular or chemical compound that has a high absorption efficiency for wavelengths of light that are emitted by the reactor.

The reaper may contain a specific chemical or molecular compound, such as gallium arsenide, crystalline silicon, or any other type of chemical or molecular compound that has a high absorption efficiency for light emitted by the reactor.

The reaper may absorb the photonic energy emitted by the reactor and may convert this energy into electrical energy. This happens through an exemplary process, such as the photovoltaic effect, or any other type of process that involves the transformation of photonic energy into electrical energy, such as a current, voltage, or resistance.

The reaper may absorb photonic energy with one single layer, may also be known as single junction, or through the composition of multiple differing physical configurations, may also be known as multi-junction. The number of layers may correspond to the peak effectiveness of the reapers ability to absorb photonic energy and convert it into electrical energy.

The reaper may also have specific material that has high-reflective capabilities to prevent the loss of photonic energy and allows it to reflect into the reaper. This material may be deposited evenly on the back of the reaper, or another location on the reaper that enables the material to reflect the light emitted by the reactor back into the reaper. This material may be made of a specific chemical or molecular compound such as copper or gold, or any other type of chemical or molecular compound that highly reflective for the specific wavelengths that are emitted by the reactor.

The reaper may also have positive and negative terminals that allow for the electrical energy to travel from the reaper onto a material connected to the reaper. This substance may be a circuit board, or any other type of material that can retain and transfer this electrical energy submitted by the reaper.

Integration into the Circuitry

The reactor may then be put onto a circuit board once the coatings, photon blasters, and reapers have all been individually added to the reactor in a way that allows for the greatest amount of photonic energy to be emitted by the reactor and harnessed by the reaper. The reaper then converts the photonic energy into electrical energy.

The electrical energy from the reaper may be transmitted into the circuit board, or another type of exemplary material that can store and emit electrical energy when connected to the reaper.

The circuit board, or another type of exemplary material that can interpret electrical energy, may either store excess electrical energy transmitted by the reaper or may transmit this electrical energy into a convertible form of current that is readable by an electronic device connected to the circuitry.

The number of reactors may differ depending upon what the circuitry is programed to transmit electrical current into. If the device the circuitry is supplying power to requires a substantial amount of power, such as a car, the number of reactors may increase to compensate for the increase in power demands.

It should be understood that all of the embodiments and examples described herein are merely exemplary and should be considered as non-limiting.

What is claimed is:

1. An apparatus substantially as described herein.

2. A system substantially as described herein.

3. A method substantially as described herein.
